(19) United States
(12) Patent Application Publication
(10) Pub. No.: US 2011/0062590 A1
(43) Pub. Date: Mar. 17, 2011

(54) Chip Stacking Device Having Re-Distribution Layer

(75) Inventors: Leo Lu, Taoyuan County (TW); Kuei-Wu Chu, Taoyuan County (TW); Jimmy Liang, Taoyuan County (TW)

(73) Assignee: MAO BANG ELECTRONIC CO., LTD., Taoyuan County (TW)

(21) Appl. No.: 12/832,776

(22) Filed: Jul. 8, 2010

(30) Foreign Application Priority Data
Sep. 17, 2009 (TW) 098217159

(51) Int. Cl. H01L 23/482

(52) U.S. Cl. 257/773; 257/E23.012

(57) ABSTRACT

A chip stacking device uses nano particle silver paste for re-distribution interconnection to form a structure having low resistance through trench filling or printing. Thus, due to its low resistance, it can effectively reduce the electrical instability due to voltage drop after current flows. Furthermore, power consumption is reduced too, with energy saved. With its stable electrical signal, its utilization scope can be further expanded to high frequency product.

### TECHNICAL FIELD OF THE DISCLOSURE

The present disclosure relates to chip stacking; more particularly, relates to using nano particle silver paste for making re-distribution wires to obtain a structure having lower resistance after trench filling or printing.

### DESCRIPTION OF THE RELATED ART

Currently, integrated circuit (IC) heads its way toward light weight, thin, short and small size as well as fast transmission speed, Hence, a capacitor in IC has to face the issue of the increase of RC time delay due to the increase in resistance by miniaturization, and that of the subsequent transmission speed reduction.

Therefore, interconnection wires are very important to semiconductor device. Many advanced semiconductor lowers the interconnection resistance and improves electro-migration resistance to improve signal transmission speed. For example, copper, which has low resistance and high electro-migration resistance, becomes the upper layer metal for multi-layered semiconductor device. However, electrical instability caused by voltage drop after current flows through is still unavoidable, while the power consumption can not be reduced effectively. Due to electrical signal instability, the product thus obtained can only be applied in low frequency field. Hence, the prior art does not fulfill all users' requests on actual use.

### SUMMARY OF THE DISCLOSURE

The main purpose of the present disclosure is to provide a nano particle silver paste used for re-distribution interconnection to obtain a structure having lower resistance after trench fill and printing.

The second purpose of the present disclosure is to provide effective means for effectively reducing electrical instability caused by voltage drop after current flows through.

The third purpose of the present disclosure is to provide means for reducing power consumption so as to save energy and power.

The fourth purpose of the present disclosure is to provide means for utilizing stable electrical signal characteristic to be applied to products having high frequency.

To achieve the above purposes, the present disclosure is a chip stacking device having a re-distribution layer (RDL), comprising a chip; at least one dielectric layer; and an RDL layer, where the chip comprises a first surface; a second surface; an electronic device; and a passivation layer; where the electronic device is stacked above the first surface and has a plurality of die pads formed on the electronic device; where the passivation layer is stacked above the electronic device with the die pads exposed; where the dielectric layer comprises a first dielectric layer and a second dielectric layer; where both the first dielectric layer and the second dielectric layer are stacked above the passivation layer; where each of the first dielectric layer and the second dielectric layer comprises an RDL trench connecting to the die pads; and where the RDL layer is coated within the RDL trench. Accordingly, a novel chip stacking device is obtained.

### BRIEF DESCRIPTIONS OF THE DRAWINGS

The present disclosure will be better understood from the following detailed descriptions of the preferred embodiments according to the present disclosure, taken in conjunction with the accompanying drawings, in w98hich

FIG. 1 is the sectional view showing the structure of the first preferred embodiment according to the present disclosure;

FIG. 2A to FIG. 2D are the first sectional view to the fourth sectional view showing the fabrication of the first preferred embodiment;

FIG. 3 is the sectional view showing the structure of the second preferred embodiment; and

FIG. 4A to FIG. 4C are the first sectional view to the third sectional view showing the fabrication of the second preferred embodiment.

### DESCRIPTION OF THE PREFERRED EMBODIMENTS

The following descriptions of the preferred embodiments are provided to understand the features and the structures of the present disclosure.

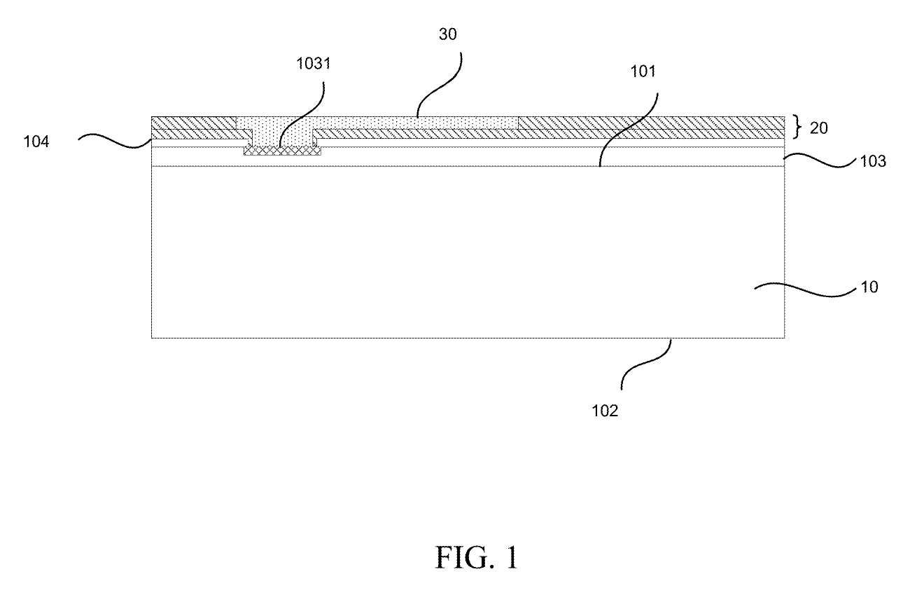

Please refer to FIG. 1, which is a sectional view showing a structure of a first preferred embodiment according to the present disclosure. As shown in the figure, a first preferred embodiment according to the present disclosure is a chip stacking device having a re-distribution layer (RDL), where nano particle silver paste is used as re-distribution interconnection material for forming a structure having low resistance after trench filling. The chip stacking device comprises a chip 10, at least one dielectric layer 20 and an RDL layer 30.

The chip 10 is made of silicon; and comprises a first surface 101, a second surface 102, an electronic device 103 and a passivation layer 104, where the electronic device 103 is a transistor stacked above the first surface 101 and has a plurality of die pads 1031 on it; and where the passivation layer 104 is staked above the electronic device 103 with the die pads 1031 exposed.

The dielectric layer 20 comprises a first dielectric layer 20a and a second dielectric layer 20b, both stacked above the passivation layer 104. Each of the first and second dielectric layers 20a,20b has an RDL trench 21 for connecting to the die pads 1031.

The RDL Layer 30 is coated within the RDL trench 21.

Thus, a novel chip stacking device having an RDL layer is obtained.

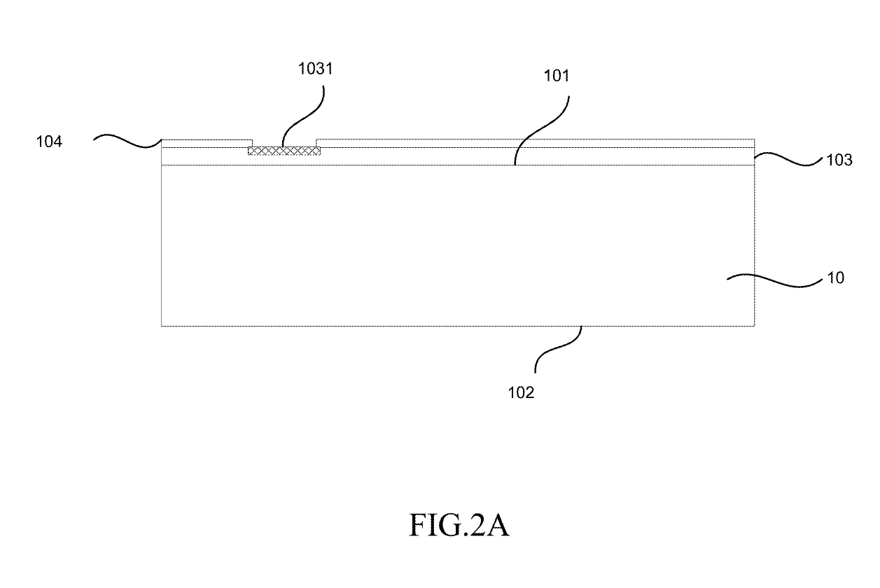

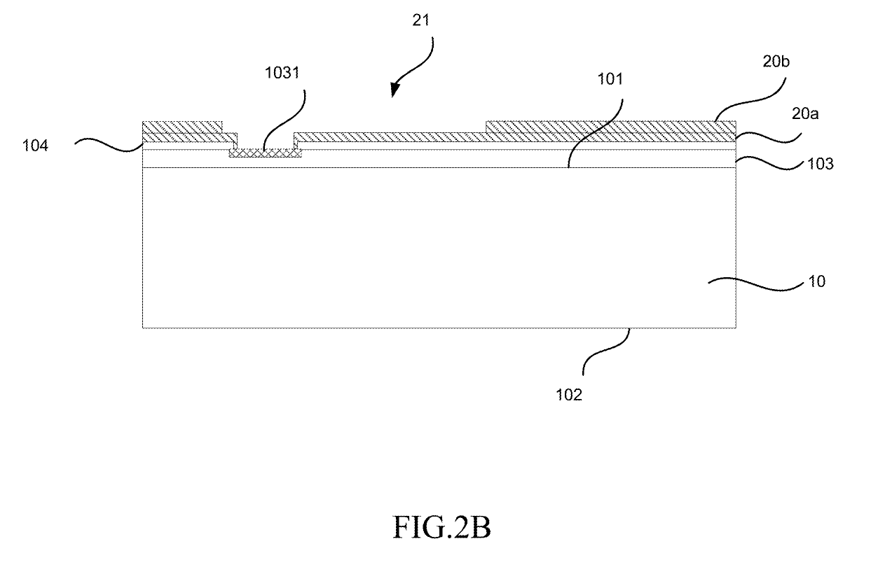

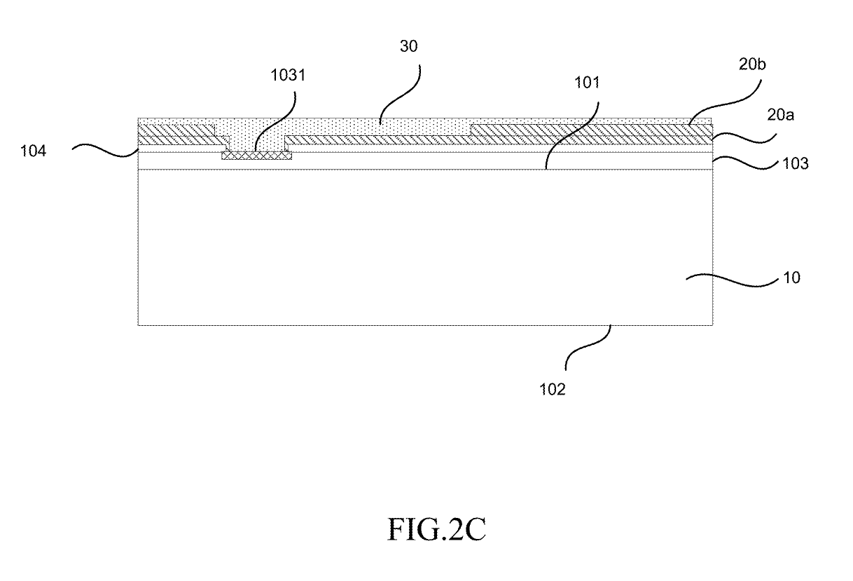

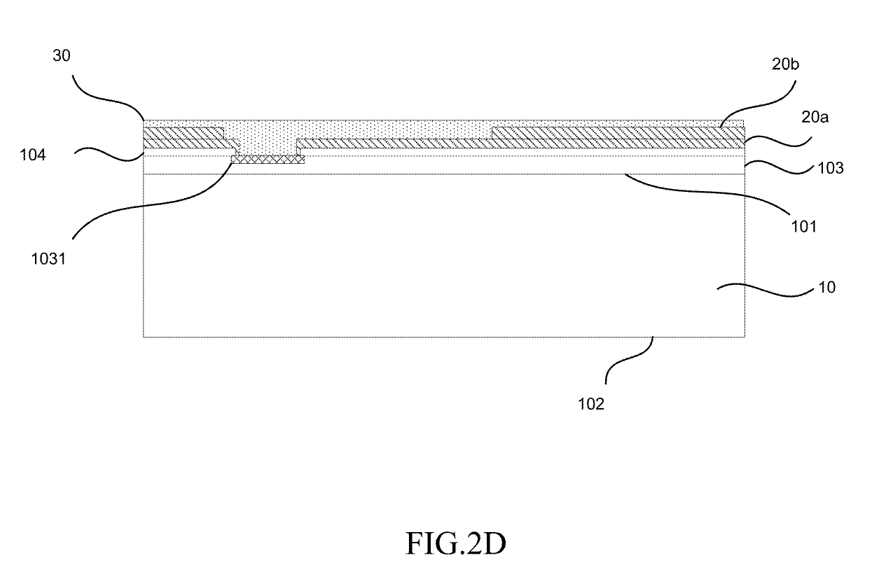

Please refer to FIG. 2A to FIG. 2D, which are a first sectional view to a fourth sectional view showing fabrication of the first preferred embodiment. As shown in the figures, on fabricating the first preferred embodiment, nano particle silver paste is used to obtain a wafer level chip size package (WLCSP):

At first, in FIG. 2A, at least one chip 10 is provided. The chip 10 is formed on and within a wafer, where the chip 10 comprises a first surface 101, a second surface 102, an electronic device 103, and a passivation layer 104; the electronic device 103 is formed above the first surface 101 and has a plurality of die pads 1031; and the passivation layer 104 is formed above the electronic device 103 with the die pads 1031 exposed.

Then, in FIG. 2B, two dielectric layers 20a,20b are coated one after another on the passivation layer 104. Then a method of trench drilling or trench punching is used to align with the die pads 1031 to form RDL trenches 21 with larger diameter. Then, in FIG. 2C, a method of full coating is used to form nano particle silver paste within the RDL trenches 21 and above the second dielectric layer 20b.

Finally, in FIG. 2D, a method of grinding is used to remove part of the nano particle silver paste and to expose the second dielectric layer 20b. Thus, an RDL layer 30 is formed and stacked within the RDL trenches 21.

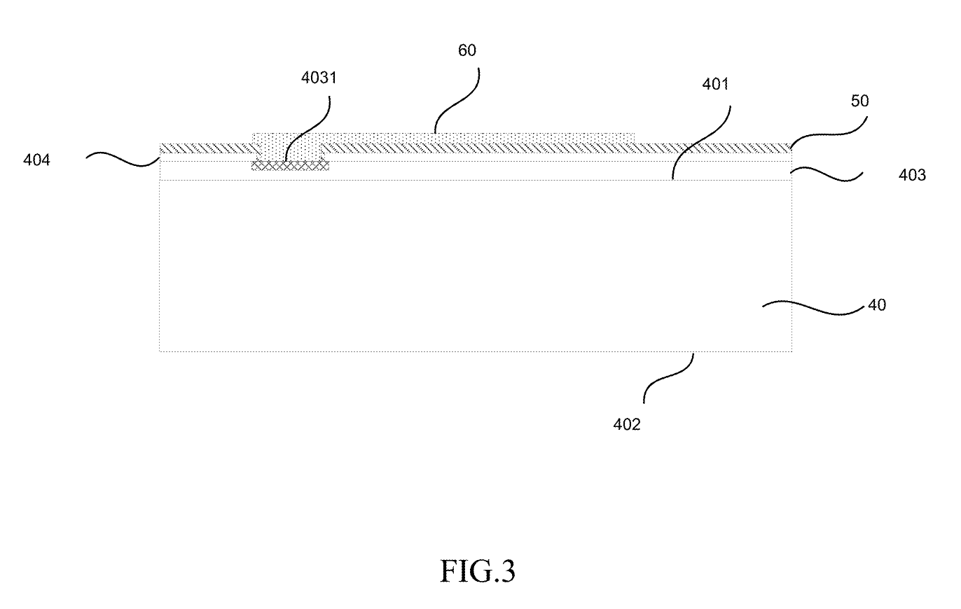

Please refer to FIG. 3, which is a sectional view showing a structure of a second preferred embodiment. As shown in the figure, a second preferred embodiment according to the present disclosure is a chip stacking device. Similarly, nano particle silver paste is used as a re-distribution interconnect material, where, after printing, a structure having low resistance is formed. The second preferred embodiment comprises a chip 40, a dielectric layer 50 and an RDL layer 60.

The chip 40 is made of silicon; and comprises a first surface 401, a second surface 402, an electronic device 403 and a passivation layer 404, where the electronic device 403 is a transistor stacked on the first surface 401 and has a plurality of die pads 4031; and where the passivation layer 404 is stacked above the electronic device 403 with the die pads 4031 exposed.

The dielectric layer 50 is stacked above the passivation layer 404 and has RDL trenches 51 for connecting to the die pads 4031.

The RDL layer 60 is printed within the RDL trenches 51 and above part of the dielectric layer 50.

Thus, a novel chip stacking device having RDL is obtained.

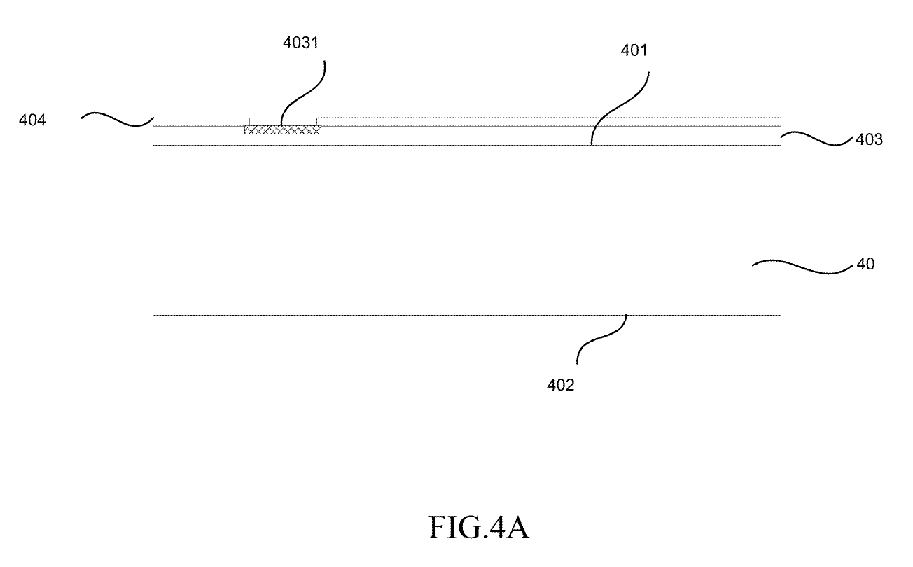

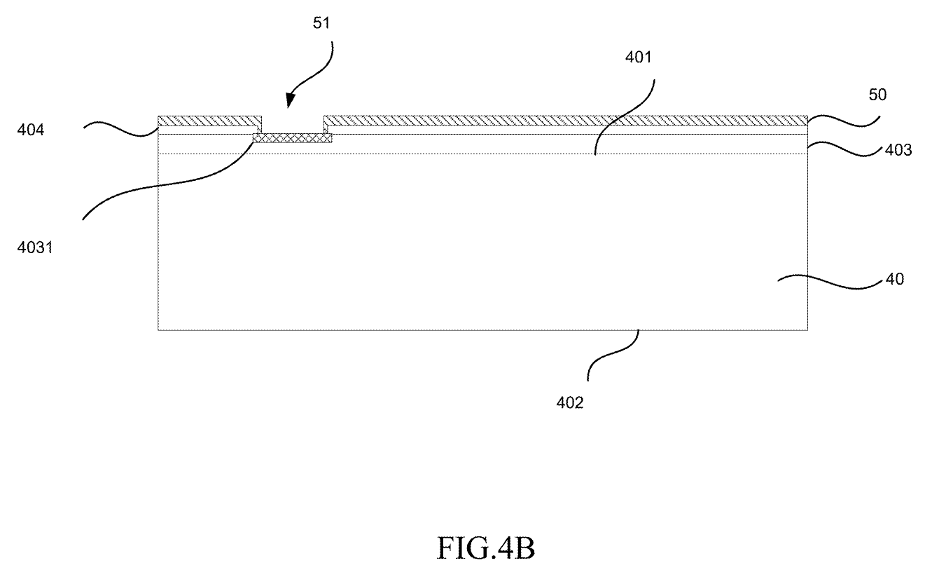

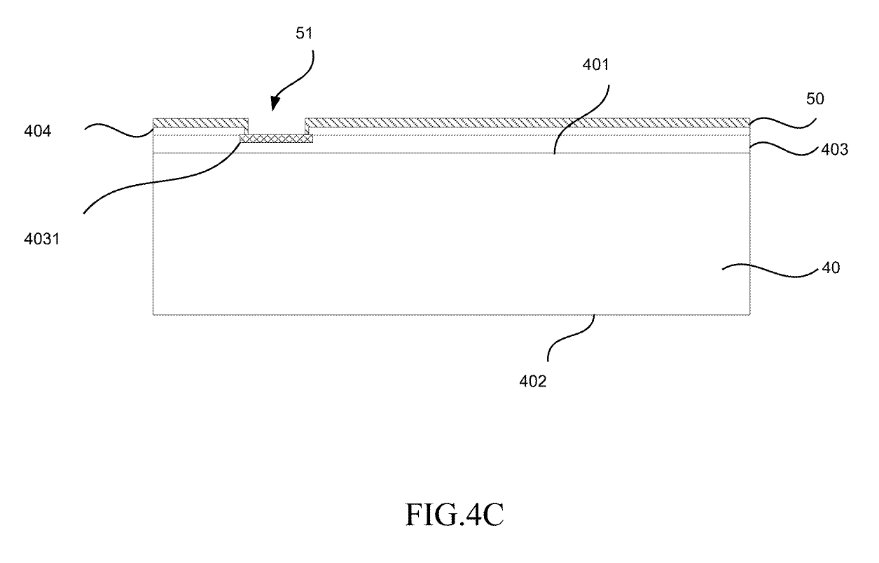

Please refer to FIG. 4A to FIG. 4C, which are a first sectional view to a third sectional view showing fabrication of the second preferred embodiment. As shown in the figure, on fabricating the second preferred embodiment, nano particle silver paste is used to obtain a WLCSP.

At first, in FIG. 4A, at least a chip 40 is provided and the chip 40 is formed within a wafer, where the chip 40 has a first surface 401, a second surface 402, an electronic device 403, and a passivation layer 404, where the electronic device 403 is formed above the first surface 401 and has a plurality of die pads 4031 formed above it; and the passivation layer 404 is formed above the electronic device 403 with the die pads 4031 exposed.

Then, in FIG. 4B, a dielectric layer 50 is coated on the passivation layer 404. Then, a method of micro-lithography is used to align with the die pads 4031 to form RDL trenches 51. Finally, in FIG. 4C, a jet printer, a screen printer or a stencil printer is used to print nano particle silver paste to further form an RDL layer 60 stacked within the RDL trenches 51 and part of the dielectric layer 50.

Therefore, a chip stacking device according to the present disclosure uses nano particle silver paste to obtain an RDL layer. That is, low resistance of the RDL layer is applied as interconnect in WLCSP packaging, and electrical instability due to voltage drop after current flows is then effectively reduced. In the mean time, power consumption can be reduced too; while energy and power saving is achieved. Due to characteristics of stable electrical signals, the present disclosure can be applied to high frequency field.

To sum up, the present disclosure is a chip stacking device, where nano particle silver paste is used for re-distribution interconnect and its low resistance effectively reduces electrical instability formed due to voltage drop after current flows; where power consumption is reduced too; and where, with energy and power saved, the present disclosure can be applied to high frequency field based on more stable electrical signal.

The preferred embodiments herein disclosed are not intended to unnecessarily limit the scope of the disclosure. Therefore, simple modifications or variations belonging to the equivalent of the scope of the claims and the instructions disclosed herein for a patent are all within the scope of the present disclosure.

What is claimed is:

1. A chip stacking device having a re-distribution layer (RDL), comprising
a chip, said chip comprising
a first surface;
a second surface;
an electronic device; and
a passivation layer,
wherein said electronic device is stacked above said first surface and has a plurality of die pads formed on said electronic device; and
wherein said passivation layer is stacked above said electronic device with said die pads exposed;
at least one dielectric layer, said dielectric layer comprising
a first dielectric layer; and
a second dielectric layer,
wherein both said first dielectric layer and said second dielectric layer are stacked above said passivation layer, and
wherein each of said first dielectric layer and said second dielectric layer comprises a RDL trench connecting to said die pads; and
an RDL layer, said RDL layer being coated within said RDL trench.

2. The chip stacking device of claim 1, wherein said RDL trench is obtained through a method selected from a group consisting of drilling and punching.

3. The chip stacking device of claim 1, wherein said RDL layer is obtained through full coating as well as grinding.
